(19) United States
(12) Patent Application Publication
(10) Pub. No.: US 2015/0259783 A1
(43) Pub. Date: Sep. 17, 2015

(54) ELECTRON BEAM APPARATUS FOR PATTERNED METAL REDUCTION AND METHOD FOR THE SAME

(71) Applicant: National Tsing Hua University, Hsin-Chu City (TW)

(72) Inventors: SHIH-EN LAI, HSIN-CHU CITY (TW); YING-CHAN HUNG, HSIN-CHU CITY (TW); PIN CHANG, HSIN-CHU CITY (TW); TRI-RUNG YEW, HSIN-CHU CITY (TW)

(21) Appl. No.: 14/310,296

(22) Filed: Jun. 20, 2014

(30) Foreign Application Priority Data
Mar. 11, 2014 (TW) 103108405

(51) Int. Cl. C23C 14/22; C23C 14/54

(52) U.S. Cl. CPC C23C 14/221; C23C 14/54

(57) ABSTRACT

An electron beam apparatus for patterned metal reduction, applied to generate metal lines or patterns on a substrate, includes an electron beam generating system with functions of collimating, focusing and scanning electron beams, an electron-transparent membrane of a vacuum chamber for allowing the electron beam to penetrate through, a stage mounted at a position to face the electron-transparent membrane, a substrate placed on the stage to face the electron-transparent membrane, a thin liquid layer containing metal ions and mounted on the substrate, and an environment control device for controlling the temperature, the pressure and the atmosphere around the substrate. A method for using the electron beam apparatus to generate the metal lines or patterns on the substrate is to focus the electron beam onto the substrate and have the electron beam to scan the substrate repeatedly along a predetermined path till a desired metal pattern is reduced on the substrate.

### CROSS REFERENCE TO RELATED APPLICATION

This application also claims priority to Taiwan Patent Application No. 103108405 filed in the Taiwan Patent Office on Mar. 11, 2014, the entire content of which is incorporated herein by reference.

### TECHNICAL FIELD

The present disclosure relates to an apparatus for reducing metal patterns on a substrate and an accompanying method for the apparatus, and more particularly to the apparatus and the method that apply the electron beam to reduce the patterned metal on the substrate. This present invention can be applied to various 3D-print fields in printing copper interconnects of a semiconductor process, silver nanowire networks of transparent conducting electrodes, surface plasma-resonance nano-gold arrays, electric inductors, the like metal patterns, and so on.

### BACKGROUND

In the art, the method for forming metal patterns on a substrate needs to firstly prepare an optical mask, and then to process an exposure step, an etching step and various steps to complete the forming of metal patterns on the substrate.

In a Taiwan patent application, publication no.200920205, the method for forming the metal patterns is to introduce a donor member having a donor substrate and a heat-transferring layer, in which the heat-transferring layer further includes a catalyst. The teaching of this application is to heat-transfer the heat-transfer layer of the donor member to a receiver member, such that the metal material can be deposited on the receiver member via growing the metal material on the catalyst.

Among various techniques of applying the reduction reaction to deposit a metal pattern or metal lines on a substrate, the conventional method of using the electron beam to reduce and thus deposit the metal onto the substrate (or called as an e-beam induced deposition) uses a thick electrolytic solution to form individual spots of metal. In other techniques, the electron beam can also be applied to reduce metallic vapors into solid metal. However, the metal lines or patterns formed by the aforesaid method usually contain unexpected impurities such as a fluoride, a carbon, a silicon and so on.

Furthermore, in this field, the method of reducing the metal by laser beams is well known to the art. However, for the diameter of the laser beam can't be substantially reduced, the line width of the metal lines or patterns formed by the laser beam would be bigger, around in the dimension of μm, which is hard to be accepted by the hi-tech art.

As stated above, the conventional methods for forming metal lines or patterns are complicate in process, the line width for the metal patterns is too big, and the reduced metal is impure. Also, in order to have continuous metal lines or patterns on the substrate, this disclosure is aimed at the aforesaid shortcomings in the art so as to provide a novel method of using an electron beam apparatus to reduce patterned metal. Further, by providing the electron beam method and the accompanying electron beam apparatus to reduce patterned metal according to the present invention, the conventional bottle neck problem for producing satisfied metal patterns can be resolved.

### SUMMARY

It is the primary object of this disclosure to provide an electron beam apparatus and the accompanying method for patterned metal reduction, by which a nano-scale metal line can be formed by a displaceable electron beam that penetrates a nano film and then projects on a thin liquid layer containing metal ions. The thickness of the thin liquid layer is less than 10 μm. In the electron beam apparatus of this disclosure, the vacuum chamber for generating the electron beams is spaced down to the substrate by a predetermined spacing. The temperature, the pressure and the atmosphere of the environment for the solution to exist are also relevantly control so as helpful to reduce the metal and also to avoid the metal-ion solution to vaporize. Hence, the main advantage by applying the apparatus and method of the present invention is at the usage of the electrolyte solution, which is cheap and nontoxic. Also, by applying the electron beams, the reduced metal patterns can have extremely pure and fine lines.

Accordingly, the electron beam apparatus for patterned metal reduction of this disclosure is applied to generate metal lines or patterns on a substrate and comprises an electron beam generating system, an electron-transparent membrane, a stage, a thin liquid layer and an environment control device. The electron beam generating system for collimating, focusing and scanning electron beams further has a vacuum chamber. The electron-transparent membrane is mounted at a bottom of the vacuum chamber to perform as a penetration window for the electron beams to penetrate therethrough. The stage is mounted under the electron-transparent membrane for positioning thereon the substrate. The thin liquid layer contains metal ions and is placed on the substrate to face the electron beams, i.e. facing the electron-transparent membrane. The environment control device is to regulate a temperature, a pressure and an atmosphere of the electron beam apparatus, particularly the area around the thin liquid layer.

Also, in this disclosure, the method for using the aforesaid electron beam apparatus to reduce patterned metal on the substrate comprises mainly a step of focusing an electron beam on the substrate and having the electron beam to scan the substrate repeatedly along a predetermined path till a desired metal pattern is reduced on the substrate.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 illustrates schematically the application of using the electron beam to reduce metal lines or patterns in accordance with this disclosure;

FIG. 2 is a schematic view of an embodiment of the electron beam apparatus for patterned metal reduction in accordance with this disclosure; and

FIG. 3 demonstrates schematically the reduction of the metal patterns by the electron beam in accordance with this disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

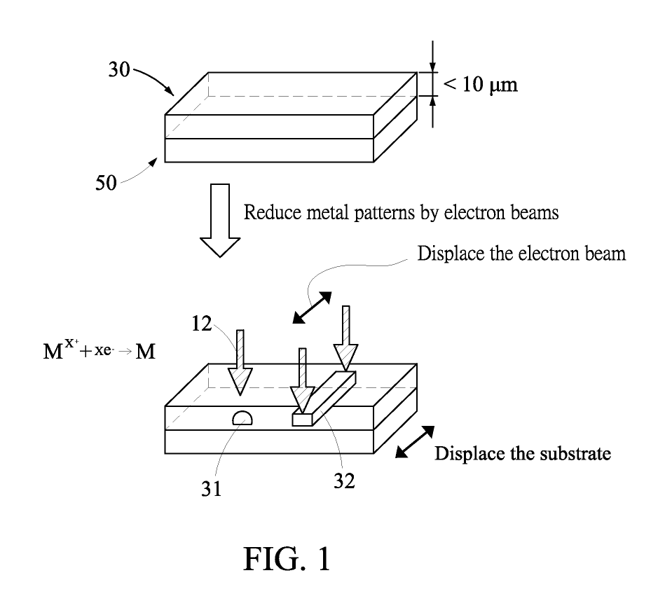

Referring now to FIG. 1, the application of using the electron beam to reduce metal lines or patterns in accordance with this disclosure is schematically demonstrated. As shown, a substrate 50 is coated a thin liquid layer 30 having a thickness less than 10 μm, in which the thin liquid layer 30 contains at least one metal-ion solution. The electron beam 12 originated from the electron source 11 is to project at the metal-ion solution on the substrate 50. For the electric polarity of the electron is negative, so the positive metal ions in the metal-ion solution can be reduced so as to form a metal spot 31 on the substrate 50. As the electron beam 12 is displaced continuously with respect to the substrate 50, a continuous metal line 32 on the substrate 50 can be formed. On the other hand, as the electron beam 12 is shifted to a specific location on the substrate 50, then a corresponding metal pattern can be reduced. In FIG. 1, M^{x+} stands for the metal ion in the metal-ion solution, e⁻is the electron, and M is the reduced metal.

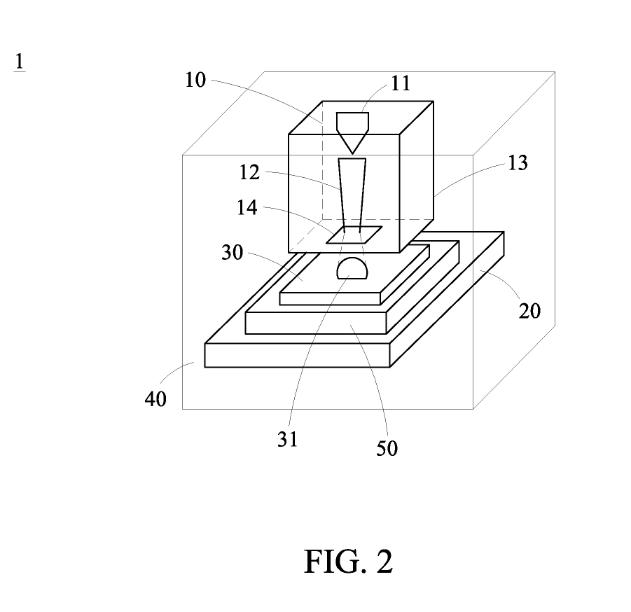

In this disclosure, an embodiment of the electron beam apparatus for patterned metal reduction 1 is provided in FIG. 2, in which a substrate 50 is introduced to directly thereon form the metal lines or patterns. The apparatus 1 includes an electron beam generating system 10, an electron-transparent membrane 14, a stage 20, a thin liquid layer 30 and an environment control device 40.

The electron beam generating system 10 further includes an electron source 11, a vacuum chamber 13. The electron beam generating system 10 is able to perform the collimating, focusing and scanning of the electron beam 12.

The electron-transparent membrane 14 supported by a membrane supporter 15 is mounted to a bottom of the vacuum chamber 13 so as to ensure the vacuum in the vacuum chamber 13 and to perform as a penetration window for the electron beam 12 to penetrate through.

The stage 20, located under the vacuum chamber 13 by a specific distance in a manner of facing electron-transparent membrane 14, is to place thereon the substrate 50.

The thin liquid layer 30 containing at least one metal-ion solution is placed on the substrate 50 by facing the electron-transparent membrane 14 so as to receive the bombarding of the electron beam 12 from the vacuum chamber 13.

The environment control device 40 is to control the temperature, the pressure and the atmosphere of the apparatus 1 for metal reduction.

In the case that a metal line or pattern is to be formed on the substrate 50 by reduction, the substrate 50 is firstly placed on the stage 20 to face the electron beam 12. The electron source 11 in the vacuum chamber 13 of the electron beam generating system 10 is then to stimulate the electron beam 12. The electron beam 12 penetrate the nano-scale electron-transparent membrane 14 to project on the thin liquid layer 30 on the substrate 50. For the thin liquid layer 30 contains positive metal ions in the solution 30, the negative electrons in the electron beam 12 would react with the positive metal ions in the solution 30 so as to reduce the metal spot 31 on the substrate 50. Further, by introducing the environment control device 40, the temperature, the pressure and the atmosphere over the substrate 50 can be controlled to benefit the metal reduction and to avoid possible evaporation of the metal-ion solution 30.

In this embodiment, the electron-transparent membrane 14 can be made of a silicon nitride, a silicon carbide, a silicon oxide, a diamond film, an aluminium oxide, an aluminium nitride, or any the like. The electron-transparent membrane 14 has a thickness less than 300 nm, preferably between 30-100 nm.

Preferably, the electron-transparent membrane 14 can be supported by surrounding a silicon base. The stage 20 is to control the substrate 50 to be correctly located at a position for metal reduction. The thin liquid layer 30 may include solutions of a copper sulfate, a chloroauric acid, a silver nitrate, a nickel sulfate, a hexachloroplatinic acid, and any the like. The thin liquid layer 30 has a thickness less than 10 μm, preferably less than 2 μm.

The environment control device 40 is to control the temperature, the pressure and the atmosphere so as feasible to process the metal reduction and to avoid possible evaporation in the thin liquid layer 30. The substrate 50 can be a silicon wafer, a III-V semiconductor chip, a II-VI semiconductor chip, a silicon oxide, and any the like.

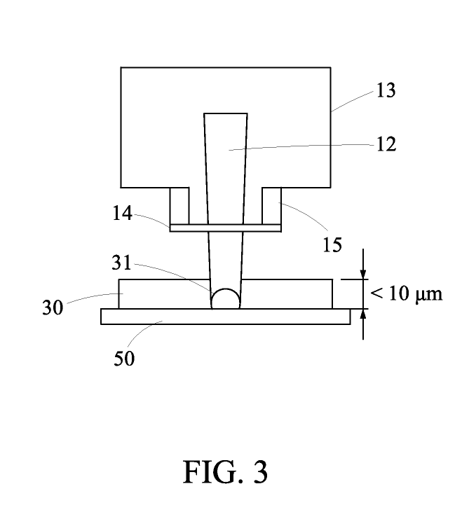

In this disclosure, a method of using the aforesaid electron beam apparatus 1 to reduce patterned metal is also provided. Referring to FIG. 3, an embodiment of this method is to reduce metal lines or patterns directly on a substrate 50. The method for using the electron beam 12 to reduce the metal pattern or line includes the steps of focusing the electron beam 12 on the substrate 50, having the electron beam 12 to scan the substrate 50 according to a predetermined path, and continuously scanning until a desired pattern is formed on the substrate 50. In this embodiment, the scanning of the electron beam 12 can be reciprocally performed along the predetermined path. The substrate 50 can be displaced a preset slow rate with respect to the electron beam 12 in accordance with the predetermined path. The line width of the metal line or pattern depends on the focusing size of the electron beam 12.

In summary, by providing the apparatus and the method in this disclosure, following objects can be achieved.

1. A nano-scale metal line can be obtained.

2. The electrolytic solution for the metal reduction is inexpensive and nontoxic.

3. The reduced metal line or pattern can be extremely fine and pure by compared to that in the art.

4. The manufacturing process for the electron beam to reduce the metal line or pattern is comparable simple with respect to the conventional method in the art.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. An electron beam apparatus for patterned metal reduction, applied to generate metal lines or patterns on a substrate, comprising:
an electron beam generating system for collimating, focusing and scanning electron beam(s), having a vacuum chamber;
an electron-transparent membrane mounted at a bottom of the vacuum chamber and performed as a penetration window for the electron beam(s);
a stage, mounted under the electron-transparent membrane for positioning thereon a substrate;
a thin liquid layer containing metal ions and placed on the substrate to face the electron beam(s); and
an environment control device for regulating a temperature, a pressure and an atmosphere of the electron beam apparatus.

2. The electron beam apparatus for patterned metal reduction according to claim 1, wherein the electron-transparent membrane is made of one of a silicon nitride, a silicon carbide, a silicon oxide, a diamond film, an aluminium oxide and an aluminium nitride.

3. The electron beam apparatus for patterned metal reduction according to claim 1, wherein the electron-transparent membrane has a thickness less than 300 nm.

4. The electron beam apparatus for patterned metal reduction according to claim 2, wherein the electron-transparent membrane has a thickness less than 300 nm.

5. The electron beam apparatus for patterned metal reduction according to claim 1, wherein the electron-transparent membrane preferably has a thickness of 30-100 nm.

6. The electron beam apparatus for patterned metal reduction according to claim 2, wherein the electron-transparent membrane preferably has a thickness of 30-100 nm.

7. The electron beam apparatus for patterned metal reduction according to claim 3, wherein the electron-transparent membrane is supported by a silicon member.

8. The electron beam apparatus for patterned metal reduction according to claim 5, wherein the electron-transparent membrane is supported by a silicon member.

9. The electron beam apparatus for patterned metal reduction according to claim 1, wherein the stage is a platform to adjust a position of the substrate.

10. The electron beam apparatus for patterned metal reduction according to claim 1, wherein the substrate is one of a silicon wafer, a III-V semiconductor chip, a II-VI semiconductor chip and a silicon oxide.

11. The electron beam apparatus for patterned metal reduction according to claim 1, wherein the thin liquid layer has a thickness less than 10 μm.

12. The electron beam apparatus for patterned metal reduction according to claim 1, wherein the thin liquid layer preferably has a thickness less than 2 μm.

13. The electron beam apparatus for patterned metal reduction according to claim 11, wherein the thin liquid layer includes a solution containing a copper sulfate, a chloroauric acid, a silver nitrate, a nickel sulfate and a hexachloroplatinic acid.

14. The electron beam apparatus for patterned metal reduction according to claim 12, wherein the thin liquid layer includes a solution containing a copper sulfate, a chloroauric acid, a silver nitrate, a nickel sulfate and a hexachloroplatinic acid.

15. The electron beam apparatus for patterned metal reduction according to claim 1, wherein the environment control device is a device to control the temperature, the pressure and the atmosphere to a condition suitable for reducing the metal pattern without vaporizing the thin liquid layer.

16. A method for using an electron beam apparatus to reduce patterned metal on a substrate, comprising a step of focusing an electron beam on the substrate and having the electron beam to scan the substrate repeatedly along a predetermined path till a desired metal pattern is reduced on the substrate.

17. The method of claim 16, using a stage to carry thereon and thus co-move the substrate while in scanning the substrate.

18. The method of claim 16, wherein the predetermined path of the electron beam is a path for reciprocally scanning the substrate.

19. The method of claim 16, wherein the substrate is moved according to the predetermined path at a slow speed.

20. The method of claim 16, wherein a line width of the desired metal pattern depends on the focusing size of the electron beam.
